(19) United States
(12) Patent Application Publication
(10) Pub. No.: US 2023/0012668 A1
(43) Pub. Date: Jan. 19, 2023

(54) SUBSTRATE PROCESSING APPARATUS, METHOD OF MANUFACTURING SEMICONDUCTOR DEVICE, NON-TRANSITORY COMPUTER-READABLE RECORDING MEDIUM AND INNER TUBE

(71) Applicant: KOKUSAI ELECTRIC CORPORATION, Tokyo (JP)

(72) Inventors: Yusaku OKAJIMA, Toyama (JP); Takatomo YAMAGUCHI, Toyama (JP); Yunosuke SAKAI, Toyama (JP); Yoshinori IMAI, Toyama (JP)

(73) Assignee: KOKUSAI ELECTRIC CORPORATION, Tokyo (JP)

(21) Appl. No.: 17/951,059

(22) Filed: Sep. 22, 2022

Related U.S. Application Data
(63) Continuation of application No. PCT/JP2020/013323, filed on Mar. 25, 2020.

(51) Int. Cl. C23C 16/455; H01L 21/02; C23C 16/458; C23C 16/44; C23C 16/34

(52) U.S. Cl. CPC C23C 16/45502; H01L 21/0217; C23C 16/4583; C23C 16/4412; C23C 16/345

(57) ABSTRACT

There is provided a substrate processing apparatus including: an inner tube including a substrate accommodating region where substrates are accommodated along an arrangement direction; an outer tube outside the inner tube; gas supply ports provided on a side wall of the inner tube along the arrangement direction; first exhaust ports provided on the side wall of the inner tube along the arrangement direction; a second exhaust port provided at an end portion of the outer tube along the arrangement direction; and a gas guide controlling gas flow in an annular space between the inner and outer tubes. A first exhaust port A is located farthest from the second exhaust port, and faces a gas supply port A. The gas guide includes a fin provided near the gas supply port A and surrounds at least a part of an outer periphery of the gas supply port A.

### CROSS-REFERENCE TO RELATED PATENT APPLICATION

This application is a bypass continuation application of PCT International Application No. PCT/JP2020/013323, filed on Mar. 25, 2020, in the WIPO, the entire contents of which are hereby incorporated by reference.

### BACKGROUND

### 1. Field

The present disclosure relates to a substrate processing apparatus, a substrate processing method, a method of manufacturing a semiconductor device, a non-transitory computer-readable recording medium and an inner tube.

### 2. Related Art

As a part of a manufacturing process of a semiconductor device, a step of supplying a gas into a process chamber in which a plurality of substrates are accommodated to process the plurality of substrates may be performed.

### SUMMARY

According to the present disclosure, there is provided a technique capable of improving a quality of a processing on a substrate when the substrate is processed.

According to one aspect of the technique of the present disclosure, there is provided a substrate processing apparatus including: an inner tube provided with a substrate accommodating region therein in which a plurality of substrates are accommodated in a multistage manner along a predetermined arrangement direction while the plurality of substrates are horizontally oriented; an outer tube provided outside the inner tube; a plurality of gas supply ports provided on a side wall of the inner tube along the arrangement direction; a plurality of first exhaust ports provided on the side wall of the inner tube along the arrangement direction; a second exhaust port provided at an end portion of the outer tube along the arrangement direction; and a gas guide configured to be capable of controlling a flow of a gas in an annular space between the inner tube and the outer tube, wherein a first exhaust port A among the plurality of first exhaust ports is located farthest from the second exhaust port, and a gas supply port A among the plurality of gas supply ports faces the first exhaust port A, and wherein the gas guide includes a fin provided in a vicinity of the gas supply port A and configured to surround at least a part of an outer periphery of the gas supply port A.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a gas supply structure of the vertical type process furnace of the substrate processing apparatus preferably used in the embodiments of the present disclosure.

FIG. 3 is a block diagram schematically illustrating a configuration of a controller and related components of the substrate processing apparatus preferably used in the embodiments of the present disclosure.

FIG. 4 is a diagram schematically illustrating a part of a horizontal cross-section of the vertical type process furnace of the substrate processing apparatus preferably used in the embodiments of the present disclosure, taken along the line B-B shown in FIG. 1.

FIGS. 5A through 5C are diagrams schematically illustrating a part of an exemplary configuration of the substrate processing apparatus preferably used in the embodiments of the present disclosure, and more specifically, FIG. 5A is a diagram schematically illustrating an outer wall of an inner tube 21 when viewed from a direction “C” shown in FIG. 4, FIG. 5B is a diagram schematically illustrating the outer wall of the inner tube 21 when viewed from a direction “D” shown in FIG. 4, and FIG. 5C is a diagram schematically illustrating the outer wall of the inner tube 21 when viewed from a direction “E” shown in FIG. 4.

FIG. 6A is a diagram schematically illustrating a flow of an exhaust gas which is discharged through a first exhaust port 41 provided in the inner tube 21 into a space between a top plate of the inner tube 21 and a top plate of an outer tube 22 and then flows toward a gas supply port 31 provided in the inner tube 21, and FIG. 6B is a diagram schematically illustrating a flow of the exhaust gas which is discharged through the first exhaust port 41 provided in the inner tube 21 into an annular space between the inner tube 21 and the outer tube 22 and then flows toward the gas supply port 31 provided in the inner tube 21.

FIGS. 7A and 7B are diagrams schematically illustrating locations where a turbulent flow of the exhaust gas is generated, wherein the exhaust gas is discharged through the first exhaust port 41 provided in the inner tube 21 into the annular space between the inner tube 21 and the outer tube 22 and then flows toward a second exhaust port 91 provided in the outer tube 22.

FIGS. 8A and 8B are diagrams schematically illustrating a part of a substrate processing apparatus according to other embodiments of the present disclosure.

### DETAILED DESCRIPTION

### Embodiments of Present Disclosure

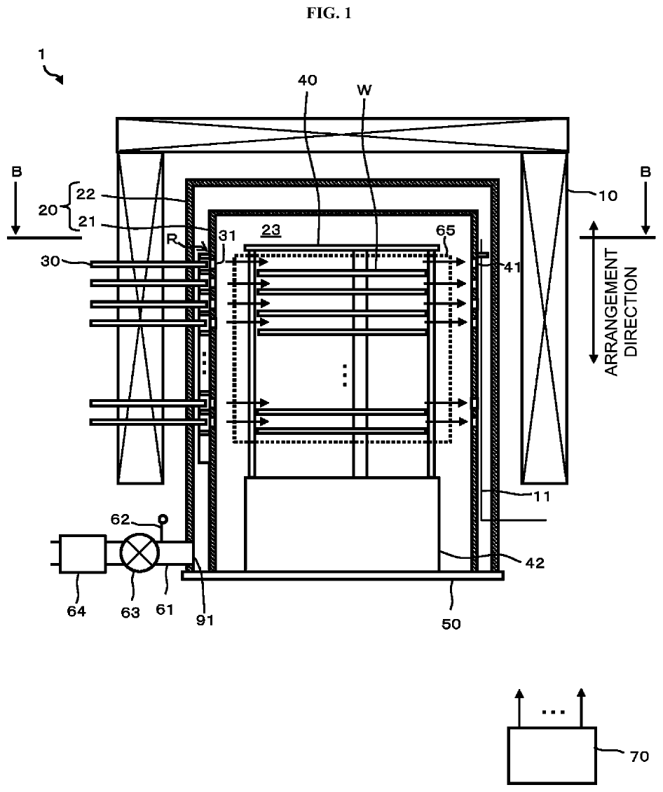

Hereinafter, one or more embodiments (also simply referred to as “embodiments”) according to the technique of the present disclosure will be described mainly with reference to FIGS. 1 through 4 and FIGS. 5A through 5C.

### (1) Configuration of Substrate Processing Apparatus

A substrate processing apparatus according to the present embodiments is used in a manufacturing process of a semiconductor device, and is configured as a vertical type substrate processing apparatus capable of collectively processing (or batch-processing) a plurality of substrates (for example, 5 substrates to 100 substrates) including a substrate to be processed. For example, the substrate to be processed may include a semiconductor wafer substrate (hereinafter, simply referred to as a “wafer”) on which a semiconductor integrated circuit device (that is, the semiconductor device) is manufactured.

As shown in FIG. 1, the substrate processing apparatus according to the present embodiments includes a vertical type process furnace 1. The vertical type process furnace 1 includes a heater 10 serving as a heating apparatus (which is a heating structure or a heating system). The heater 10 is of a cylindrical shape, and is installed perpendicular to an installation floor (not shown) of the substrate processing apparatus while being supported by a heater base (not shown) serving as a support plate. The heater 10 also functions as an activator (also referred to as an “exciter”) capable of activating (or exciting) a gas by heat.

A reaction tube 20 constituting a reaction vessel (which is a process vessel) is provided in an inner side of the heater 10 to be aligned in a manner concentric with the heater 10. For example, the reaction tube 20 is embodied by a double tube configuration including an inner tube 21 serving as an inner reaction tube and an outer tube 22 serving as an outer reaction tube and provided to surround the inner tube 21 to be aligned in a manner concentric with the inner tube 21. For example, each of the inner tube 21 and the outer tube 22 is made of a heat resistant material such as quartz (SiO₂) and silicon carbide (SiC). For example, each of the inner tube 21 and the outer tube 22 is of a cylindrical shape with a closed upper end and an open lower end.

A process chamber 23 in which a plurality of wafers including a wafer W are processed is provided in the inner tube 21. Hereinafter, the plurality of wafers including the wafer W may also be simply referred to as wafers W. The process chamber 23 is configured such that the wafers W are capable of being accommodated in a boat 40 described later in the process chamber 23 in a multistage manner in a predetermined arrangement direction (for example, a vertical direction according to the present embodiments) while the wafers W are horizontally oriented in the boat 40. In the present specification, a direction in which the wafers W are arranged in the process chamber 23 may also be referred to as an “arrangement direction”. Further, a region in the process chamber 23 in which the wafers W are accommodated along the arrangement direction while the wafers W are horizontally oriented may also be referred to as a “substrate accommodating region 65”.

A seal cap 50 serving as a furnace opening lid capable of airtightly sealing (or closing) a lower end opening of the reaction tube 20 is provided under the reaction tube 20. For example, the seal cap 50 is made of a metal material such as stainless steel (SUS), and is of a disk shape. An O-ring (not shown) serving as a seal is provided on an upper surface of the seal cap 50 so as to be in contact with a lower end of the reaction tube 20. The seal cap 50 is configured to be elevated or lowered in the vertical direction by a boat elevator (not shown) serving as an elevator. The boat elevator serves as a transfer system (which is a transfer structure) that transfers (or loads) the boat 40 and the wafers W accommodated in the boat 40 into the process chamber 23 or transfers (or unloads) the boat 40 and the wafers W accommodated in the boat 40 out of the process chamber 23 by elevating or lowering the seal cap 50.

A substrate loading/unloading port (not shown) is provided below the seal cap 50. The wafer W is transferred into or out of a transfer chamber (not shown) by a transfer robot (not shown) through the substrate loading/unloading port. In the transfer chamber, the wafer W may be transferred (loaded) into the boat 40, and the wafer W may be transferred (unloaded) out of the boat 40.

The boat 40 serving as a substrate support (or a substrate retainer) is configured such that the wafers W (for example, 5 wafers to 100 wafers) are accommodated (or supported) in the boat 40 in the predetermined arrangement direction (for example, the vertical direction according to the present embodiments) while the wafers W are horizontally oriented with their centers aligned with one another with a predetermined gap therebetween in the multistage manner. For example, the boat 40 is made of a heat resistant material such as quartz and SiC. A heat insulator 42 is provided below the boat 40. For example, a heat insulating cylinder made of a heat resistant material such as quartz and SiC may be used as the heat insulator 42. Alternatively, for example, a plurality of heat insulating plates made of a heat resistant material such as quartz and SiC and horizontally oriented in a multistage manner may be used as the heat insulator 42.

In the reaction tube 20, a plurality of nozzles including a nozzle 30 serving as a gas supplier (which is a gas supply structure) through which the gas such as a source gas and a reactive gas is supplied toward the inner tube 21 are provided so as to be arranged in the predetermined arrangement direction (for example, the vertical direction according to the present embodiments) and so as to penetrate the heater 10 and the outer tube 22 through side walls of the heater 10 and the outer tube 22. Hereinafter, the plurality of nozzles including the nozzle 30 may also be simply referred to as nozzles 30. Further, the nozzles 30 are provided corresponding to the wafers W accommodated in the substrate accommodating region 65, respectively. Further, the nozzles 30 are provided such that the gas is capable of being ejected toward surfaces of the wafers W accommodated in the substrate accommodating region 65 through the nozzles 30 in a direction substantially parallel to the surfaces of the wafers W.

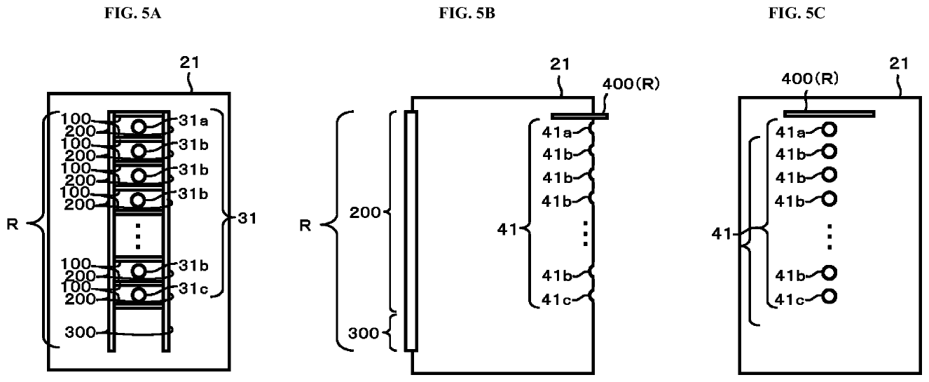

As shown in FIG. 5A, a plurality of gas supply ports including a gas supply port 31 through which the gas supplied through the nozzles 30 is introduced into the inner tube 21 are provided on a side wall of the inner tube 21 so as to be arranged in the predetermined arrangement direction (for example, the vertical direction according to the present embodiments). Hereinafter, the plurality of gas supply ports including the gas supply port 31 may also be simply referred to as gas supply ports 31. Further, the gas supply ports 31 are provided corresponding to the wafers W accommodated in the substrate accommodating region 65, respectively. Further, the gas supply ports 31 are provided at positions facing front ends (tips) of the nozzles 30, respectively. In the present specification, among the gas supply ports 31, a gas supply port located at an uppermost location and farthest from a second exhaust port 91 described later (and facing a first exhaust port 41a described later) may also be referred to as a “gas supply port A”, a “gas supply port 31a” or an “uppermost gas supply port 31a”. Further, among the gas supply ports 31, gas supply ports other than the gas supply port 31a and respectively facing a plurality of first exhaust ports 41b described later may also be referred to as “gas supply ports B”, “gas supply ports 31b” or “intermediate gas supply ports 31b”. In the present specification, among the gas supply ports 31b, a gas supply port located at a lowermost location and closest to the second exhaust port 91 described later (and facing a first exhaust port 41c described later) may also be referred to as a “gas supply port C”, a “gas supply port 31c” or a “lowermost gas supply port 31c”.

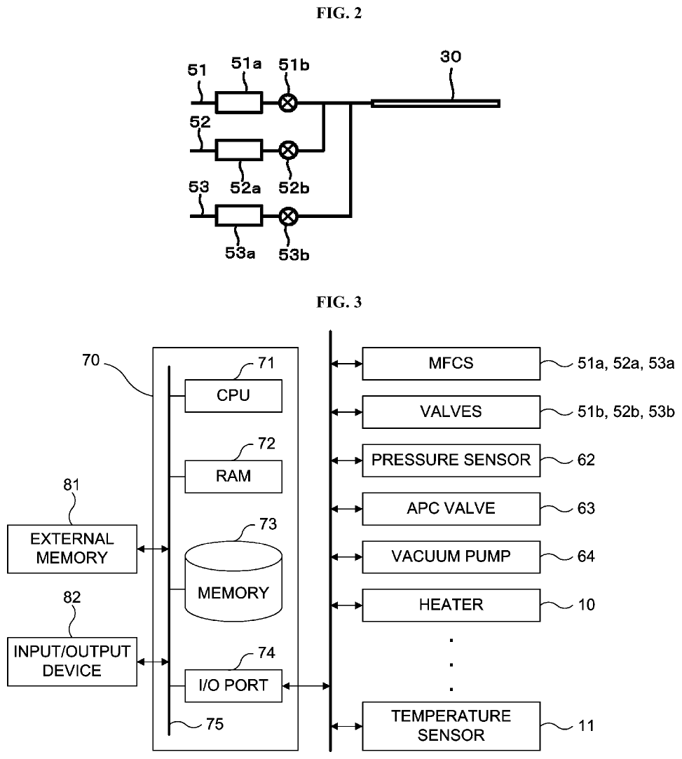

As shown in FIG. 2, a gas supply pipe 51 is connected to each of the nozzles 30. A mass flow controller (MFC) 51a serving as a flow rate controller (which is a flow rate controlling structure) and a valve 51b serving as an opening/closing valve are sequentially provided at the gas supply pipe 51 in this order from an upstream side to a downstream side of the gas supply pipe 51 along a gas flow direction. Gas supply pipes 52 and 53 are connected to the gas supply pipe 51 at a downstream side of the valve 51b. Mass flow controllers (also simply referred to as “MFCs”) 52a and 53a and valves 52b and 53b are sequentially provided at the gas supply pipes 52 and 53, respectively, in this order from upstream sides to downstream sides of the gas supply pipes 52 and 53 in the gas flow direction.

For example, as the source gas, a silane-based gas containing silicon (Si) serving as a main element constituting a film to be formed on the wafer W is supplied into the process chamber 23 through the gas supply pipe 51 provided with the MFC 51a and the valve 51b and the nozzle 30. For example, as the silane-based gas, hexachlorodisilane (Si₂Cl₆, abbreviated as HCDS) gas may be used.

For example, as the reactive gas, a nitriding gas is supplied into the process chamber 23 through the gas supply pipe 52 provided with the MFC 52a and the valve 52b, the gas supply pipe 51 and the nozzle 30. For example, as the nitriding gas, ammonia (NH₃) gas may be used.

For example, as an inert gas, a nitrogen (N₂) gas is supplied into the process chamber 23 through the gas supply pipe 53 provided with the MFC 53a and the valve 53b, the gas supply pipe 51 and the nozzle 30. For example, the N₂ gas serves as a purge gas, a dilution gas or a carrier gas.

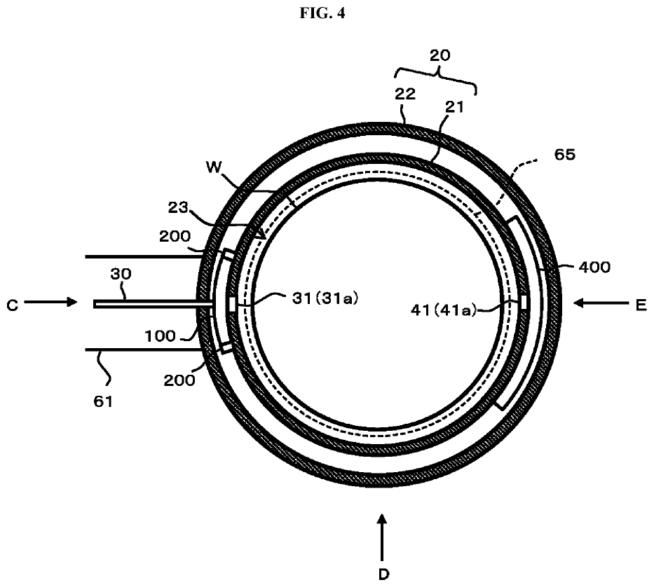

As shown in FIGS. 4 and 5B, a plurality of first exhaust ports including a first exhaust port 41 are provided on the side wall of the inner tube 21 at positions facing the gas supply ports 31 via the substrate accommodating region 65. Hereinafter, the plurality of first exhaust ports including the first exhaust port 41 may also be simply referred to as first exhaust ports 41. As shown in FIGS. 1 and 5C, the first exhaust ports 41 are provided so as to be arranged in the predetermined arrangement direction (for example, the vertical direction according to the present embodiments). The first exhaust ports 41 are configured such that the gas supplied through the gas supply ports 31 into the inner tube 21 is discharged (or exhausted) out of the inner tube 21 through the first exhaust ports 41. Further, the first exhaust ports 41 are provided corresponding to the gas supply ports 31 (that is, the wafers W accommodated in the substrate accommodating region 65), respectively. In the present specification, among the first exhaust ports 41, a first exhaust port located at an uppermost location and farthest from the second exhaust port 91 described later may also be referred to as an “exhaust port A”, the “first exhaust port 41a” or an “uppermost first exhaust port 41a”. Further, among the first exhaust ports 41, a plurality of first exhaust ports other than the first exhaust port 41a may also be referred to as “exhaust ports B”, the “first exhaust ports 41b” or “intermediate first exhaust ports 41b”. In the present specification, among the first exhaust ports 41b, a first exhaust port located at a lowermost location and closest to the second exhaust port 91 described later may also be referred to as an “exhaust port C”, the “first exhaust port 41c” or a “lowermost first exhaust port 41c”.

The second exhaust port 91 is provided at an end portion (for example, a lower end portion according to the present embodiments) of the outer tube 22 wherein the end portion is defined on the basis of the predetermined arrangement direction (for example, the vertical direction according to the present embodiments) such that the gas discharged from the inner tube 21 to the outer tube 22 through the first exhaust ports 41 (that is, an exhaust gas flowing in an annular space between the inner tube 21 and the outer tube 22) is discharged (or exhausted) out of the reaction tube 20 through the second exhaust port 91. An exhaust pipe 61 is connected to the second exhaust port 91. A vacuum pump 64 serving as a vacuum exhaust apparatus is connected to the exhaust pipe 61 through a pressure sensor 62 serving as a pressure detector (which is a pressure detecting structure) configured to detect an inner pressure of the reaction tube 20 and an APC (Automatic Pressure Controller) valve 63 serving as a pressure regulator (which is a pressure adjusting structure). With the vacuum pump 64 in operation, the APC valve 63 may be opened or closed to perform a vacuum exhaust of an inner atmosphere of the process chamber 23 or to stop the vacuum exhaust. In addition, with the vacuum pump 64 in operation, an opening degree of the APC valve 63 may be adjusted in order to adjust an inner pressure of the process chamber 23 based on pressure information detected by the pressure sensor 62. An exhauster (which is an exhaust structure, an exhaust system or an exhaust line) is constituted mainly by the exhaust pipe 61, the APC valve 63 and the pressure sensor 62.

A gas guide R is provided between the inner tube 21 and the outer tube 22. The gas guide R is configured to be capable of controlling a flow of the gas in the annular space between the inner tube 21 and the outer tube 22 (hereinafter, also referred to as an “exhaust buffer space”), that is, a flow (also referred to as an “exhaust path”) of the exhaust gas discharged into the exhaust buffer space through each of the first exhaust ports 41 and flowing toward the second exhaust port 91. A specific configuration of the gas guide R will be described later.

A temperature sensor 11 serving as a temperature detector is installed between the inner tube 21 and the outer tube 22. A state of electric conduction to the heater 10 may be adjusted based on temperature information detected by the temperature sensor 11 such that a desired temperature distribution of an inner temperature of the process chamber 23 can be obtained. For example, the temperature sensor 11 is L-shaped, and is provided along an outer wall of the inner tube 21.

As shown in FIG. 3, a controller 70 serving as a control device (control structure) is constituted by a computer including a CPU (Central Processing Unit) 71, a RAM (Random Access Memory) 72, a memory 73 and an input/output (I/O) port 74. The RAM 72, the memory 73 and the I/O port 74 may exchange data with the CPU 71 through an internal bus 75. For example, an external memory 81 and an input/output device 82 constituted by a component such as a touch panel are connected to the controller 70.

For example, the memory 73 is configured by a component such as a flash memory and a hard disk drive (HDD). For example, data such as a control program configured to control operations of the substrate processing apparatus and a process recipe containing information on sequences and conditions of a method of manufacturing a semiconductor device described later may be readably stored in the memory 73. The process recipe is obtained by combining steps (or processes) of the method of manufacturing the semiconductor device described later such that the controller 70 can execute the steps to acquire a predetermined result, and functions as a program. Hereinafter, the process recipe and the control program may be collectively or individually referred to as a “program”. In addition, the process recipe may also be simply referred to as a “recipe”. In the present specification, the term “program” may refer to the recipe alone, may refer to the control program alone, or may refer to both of the recipe and the control program. The RAM 72 functions as a memory area (work area) where the program or data read by the CPU 71 is temporarily stored.

The I/O port 74 is connected to the above-described components such as the MFCs 51a, 52a and 53a, the valves 51b, 52b and 53b, the pressure sensor 62, the APC valve 63, the vacuum pump 64, the heater 10 and the temperature sensor 11.

The CPU 71 is configured to read the control program from the memory 73 and execute the read control program. In addition, the CPU 71 is configured to read the recipe from the memory 73 in accordance with an operation command inputted from the input/output device 82. According to the contents of the read recipe, the CPU 71 may be configured to be capable of controlling various operations such as flow rate adjusting operations for various gases by the MFCs 51a, 52a and 53a, opening and closing operations of the valves 51b, 52b and 53b, an opening and closing operation of the APC valve 63, a pressure adjusting operation by the APC valve 63 based on the pressure sensor 62, a start and stop of the vacuum pump 64, a temperature adjusting operation by the heater 10 based on the temperature sensor 11 and an elevating and lowering operation of the boat 40 by the elevator (not shown).

The controller 70 may be embodied by installing the above-described program stored in the external memory 81 into the computer. For example, the external memory 81 may include a magnetic tape, a magnetic disk such as a hard disk drive (HDD), an optical disk such as a CD, a magneto-optical disk such as an MO and a semiconductor memory such as a USB memory. The memory 73 or the external memory 81 may be embodied by a non-transitory computer readable recording medium. Hereinafter, the memory 73 and the external memory 81 may be collectively or individually referred to as a “recording medium”. In the present specification, the term “recording medium” may refer to the memory 73 alone, may refer to the external memory 81 alone, and may refer to both of the memory 73 and the external memory 81. Further, instead of using the external memory 81, a communication structure (or a communication interface) such as the Internet and a dedicated line may be used for providing the program to the computer.

### (2) Substrate Processing

Hereinafter, as a part of the manufacturing process of the semiconductor device, an exemplary film-forming sequence of a substrate processing (also referred to as a “film-forming process”) of forming a film on the wafer W serving as the substrate will be described. The substrate processing is performed by using the substrate processing apparatus described above. In the following description, operations of components constituting the substrate processing apparatus are controlled by the controller 70.

In the film-forming sequence according to the present embodiments, a silicon nitride film (also simply referred to as a “SiN film”) is formed on the wafer W by performing a cycle a predetermined number of times (n times, n is an integer equal to or greater than 1), wherein the cycle includes a first step of supplying the HCDS gas serving as the source gas to the wafer W accommodated in the process vessel (that is, the process chamber 23) and a second step of supplying the NH₃ gas serving as the reactive gas to the wafer W accommodated in the process chamber 23, and the steps of the cycle are performed non-simultaneously (that is, the steps of the cycle are performed alternately without overlapping with each other).

In the present specification, the film-forming process described above may be represented, for simplicity's sake, as follows. Film-forming processes of other embodiments, which will be described later, will be also represented in the same manner.

(HCDS→NH₃)×n⇒SiN

<Wafer Charging Step and Boat Loading Step>

After the wafers W are charged (transferred) into the boat 40 (wafer charging step), the boat 40 charged with the wafers W is elevated by the boat elevator (not shown) and loaded (transferred) into the process chamber 23 (boat loading step). With the boat 40 loaded into the process chamber 23, the seal cap 50 seals the lower end of the reaction tube 20 via the O-ring (not shown).

<Pressure Adjusting Step and Temperature Adjusting Step>

The vacuum pump 64 vacuum-exhausts (decompresses and exhausts) the process chamber 23 (that is, a space in which the wafers W are accommodated) such that the inner pressure of the process chamber 23 reaches and is maintained at a desired pressure (vacuum degree). When vacuum-exhausting the process chamber 23, the inner pressure of the reaction tube 20 is measured by the pressure sensor 62, and the APC valve 63 is feedback-controlled based on the pressure information measured by the pressure sensor 62 such that the inner pressure of the process chamber 23 is adjusted to the desired pressure (pressure adjusting step). The vacuum pump 64 continuously vacuum-exhausts the process chamber 23 until at least a processing of the wafer W is completed. In addition, the heater 10 heats the process chamber 23 such that a temperature of the wafer W accommodated in the process chamber 23 reaches and is maintained at a desired film-forming temperature. When heating the process chamber 23, the state of the electric conduction to the heater 10 is feedback-controlled based on the temperature information detected by the temperature sensor 11 such that the desired temperature distribution of the inner temperature of the process chamber 23 is obtained (temperature adjusting step). The heater 10 continuously heats the process chamber 23 until at least the processing of the wafer W is completed.

<Film-Forming Step>

Thereafter, as a film-forming step, the following two steps, that is, the first step and the second step are sequentially performed.

<First Step>

In the first step, the HCDS gas is supplied to each of the wafers W in the process chamber 23.

Specifically, the valve 51b is opened, and the HCDS gas is supplied into the gas supply pipe 51. After a flow rate of the HCDS gas is adjusted by the MFC 51a, the HCDS gas whose flow rate is adjusted is supplied into the process chamber 23 (that is, into the inner tube 21) through the nozzle 30 and the gas supply ports 31. The HCDS gas supplied into the inner tube 21 flows in a direction parallel to the surfaces of the wafers W (that is, a horizontal direction), is discharged out of the inner tube 21 through the first exhaust ports 41, and is exhausted through the second exhaust port 91 via the annular space (that is, the exhaust buffer space) between the inner tube 21 and the outer tube 22. Thereby, the HCDS gas is supplied to each of the wafers W. When the HCDS gas is supplied to the wafers W, the valve 53b is opened, and the N₂ gas is supplied into the gas supply pipe 53. After a flow rate of the N₂ gas is adjusted by the MFC 53a, the N₂ gas whose flow rate is adjusted is supplied into the inner tube 21 through the nozzle 30 and the gas supply ports 31. The N₂ gas serves as the carrier gas.

In the first step, for example, the inner pressure of the process chamber 23 may be set to a pressure within a range from 0.1 Torr to 30 Torr, preferably from 0.2 Torr to 20 Torr, and more preferably from 0.3 Torr to 13 Torr. For example, a supply flow rate of the HCDS gas may be set to a flow rate within a range from 0.1 slm to 10 slm, preferably from 0.2 slm to 2 slm. For example, a supply flow rate of the N₂ gas may be set to a flow rate within a range from 0.1 slm to 20 slm. For example, a supply time of the HCDS gas may be set to a time within a range from 0.1 second to 60 seconds, preferably from 0.5 second to 5 seconds. For example, a temperature of the heater 10 may be set such that the temperature of the wafer W reaches and is maintained at a temperature within a range from 200° C. to 900° C., preferably from 300° C. to 850° C., and more preferably from 400° C. to 750° C.

By supplying the HCDS gas to each of the wafers W, a silicon-containing layer serving as a first layer is formed on an outermost surface of each of the wafers W.

After the first layer is formed, the valve 51b is closed to stop a supply of the HCDS gas into the inner tube 21. When stopping the supply of the HCDS gas, with the APC valve 63 open, the vacuum pump 64 vacuum-exhausts the process chamber 23 such that the HCDS gas remaining in the process chamber 23 which did not react or which contributed to the formation of the first layer is removed from the process chamber 23. When vacuum-exhausting the process chamber 23, with the valve 53b open, the N₂ gas is continuously supplied into the process chamber 23. The N₂ gas serves as the purge gas, which improves an efficiency of removing the gas (such as the HCDS gas) remaining in the process chamber 23 out of the process chamber 23. After a purge process of purging the process chamber 23 by the N₂ gas is completed, the valve 53b is closed to stop a supply of the N₂ gas into the process chamber 23.

<Second Step>

After the first step is completed, in the second step, the NH₃ gas is supplied to each of the wafers W in the process chamber 23.

Specifically, the valve 52b is opened, and the NH₃ gas is supplied into the gas supply pipe 52. After a flow rate of the NH₃ gas is adjusted by the MFC 52a, the NH₃ gas whose flow rate is adjusted is supplied into the process chamber 23 (that is, into the inner tube 21) through the gas supply pipe 51, the nozzle 30 and the gas supply ports 31. The NH₃ gas supplied into the inner tube 21 flows in the direction parallel to the surfaces of the wafers W (that is, the horizontal direction), is discharged out of the inner tube 21 through the first exhaust ports 41, and is exhausted through the second exhaust port 91 via the exhaust buffer space between the inner tube 21 and the outer tube 22. Thereby, the NH₃ gas is supplied to each of the wafers W. When the NH₃ gas is supplied to the wafers W, the valve 53b is opened, and the N₂ gas is supplied into the gas supply pipe 53. After the flow rate of the N₂ gas is adjusted by the MFC 53a, the N₂ gas whose flow rate is adjusted is supplied into the inner tube 21 through the nozzle 30 and the gas supply ports 31. The N₂ gas serves as the carrier gas.

In the second step, for example, the inner pressure of the process chamber 23 may be set to a pressure within a range from 0.1 Torr to 30 Torr, preferably from 0.2 Torr to 20 Torr, and more preferably from 0.3 Torr to 13 Torr. For example, a supply flow rate of the NH₃ gas may be set to a flow rate within a range from 0.1 slm to 10 slm, preferably from 0.2 slm to 2 slm. For example, the supply flow rate of the N₂ gas may be set to a flow rate within a range from 0.1 slm to 20 slm. For example, a supply time of the NH₃ gas may be set to a time within a range from 0.1 second to 60 seconds, preferably from 0.5 second to 5 seconds. For example, the temperature of the heater 10 may be set such that the temperature of the wafer W reaches and is maintained at a temperature within a range from 200° C. to 900° C., preferably from 300° C. to 850° C., and more preferably from 400° C. to 750° C.

The NH₃ gas supplied to each of the wafers W reacts with at least a part of the first layer (that is, the silicon-containing layer) formed on each of the wafers W in the first step. Thereby, the first layer is thermally nitrided under a non-plasma atmosphere and changed (modified) into a second layer containing silicon (Si) and nitrogen (N), that is, a silicon nitride layer (also simply referred to as a “SiN layer”).

After the second layer (SiN layer) is formed, the valve 52b is closed to stop a supply of the NH₃ gas into the inner tube 21. Then, a substance such as the NH₃ gas remaining in the process chamber 23 and reaction by-products is removed from the process chamber 23 in accordance with the same process sequences as those of the first step.

<Performing Predetermined Number of Times>

By performing the cycle wherein the first step and the second step described above are performed non-simultaneously (that is, performed alternately without overlapping with each other) the predetermined number of times (n times, n is an integer equal to or greater than 1), it is possible to form the SiN film of a predetermined thickness on each of the wafers W. It is preferable that the cycle described above is performed a plurality of times. That is, it is preferable that the cycle is repeatedly performed the plurality of times until the SiN film of a desired thickness is obtained by controlling the second layer formed in each cycle to be thinner than the SiN film of the desired thickness and by stacking the second layer by repeatedly performing the cycle.

<After-Purge Step and Returning to Atmospheric Pressure Step>

After the film-forming step is completed and the SiN film of the predetermined thickness is formed, the N₂ gas is supplied into the reaction tube 20 and exhausted through the exhaust pipe 61. As a result, the inner atmosphere of the process chamber 23 is purged, and a substance such as a residual gas in the process chamber 23 and the reaction by-products in the process chamber 23 is removed from the process chamber 23 (after-purge step). Thereafter, the inner atmosphere of the process chamber 23 is replaced with the inert gas (substitution by the inert gas), and the inner pressure of the process chamber 23 is returned to the normal pressure (returning to atmospheric pressure step).

<Boat Unloading Step and Wafer Discharging Step>

Thereafter, the seal cap 50 is lowered by the boat elevator (not shown), and the lower end of the reaction tube 20 is opened. Then, the boat 40 with the processed wafers W supported therein is unloaded (transferred) out of the reaction tube 20 (boat unloading step). Then, the processed wafers W are discharged (transferred) from the boat 40 after the boat 40 is unloaded out of the reaction tube 20 (wafer discharging step).

### (3) Configuration of Gas Guide R

Hereinafter, a configuration of the gas guide R capable of controlling the flow of the exhaust gas (that is, the exhaust path) in the space between the inner tube 21 and the outer tube 22 will be described. As described above, in the present specification, the space between the inner tube 21 and the outer tube 22 is also referred to as the “exhaust buffer space”.

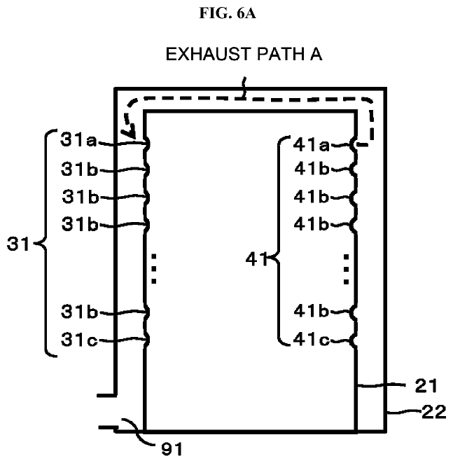

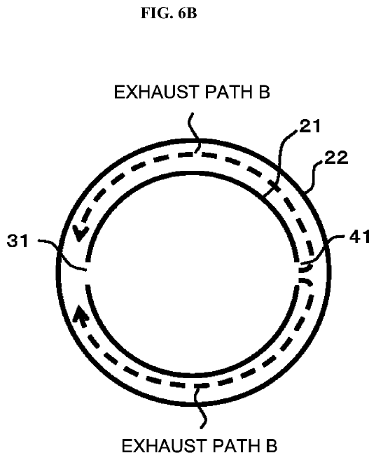

FIGS. 6A and 6B are diagrams schematically illustrating a flow path of the exhaust gas in the exhaust buffer space when the gas guide R is not provided in the exhaust buffer space.

First, as shown in FIG. 6A, the exhaust gas discharged through the first exhaust port 41 such as the first exhaust port 41a may flow toward the gas supply port 31 such as the gas supply port 31a via a space (also referred to as an “upper buffer space”) between a top plate of the inner tube 21 and a top plate of the outer tube 22 in the exhaust buffer space, and then may flow into the inner tube 21 through the gas supply port 31. The flow path of the exhaust gas in such a case is illustrated by “EXHAUST PATH A” in FIG. 6A. In particular, the gas discharged through the first exhaust port 41a located farthest from the second exhaust port 91 may easily flow into the upper buffer space, and then may easily flow into the gas supply port 31a facing the first exhaust port 41a along the vertical direction (up/down direction). The exhaust gas that has flowed into the inner tube 21 serves as a factor of deteriorating a quality of the substrate processing.

Further, as shown in FIG. 6B, the exhaust gas discharged through the first exhaust port 41 may flow toward the gas supply port 31 via an annular space (when viewed from above) (also referred to as a “side buffer space”) between the side wall of the inner tube 21 and a side wall of the outer tube 22 in the exhaust buffer space, and then may flow into the inner tube 21 through the gas supply port 31. The flow path of the exhaust gas in such a case is illustrated by “EXHAUST PATH B” in FIG. 6B. In particular, the gas discharged through the first exhaust port 41a located farthest from the second exhaust port 91 may easily flow into the side buffer space, and then may easily flow into the gas supply port 31a facing the first exhaust port 41a along the horizontal direction (left/right direction). As described above, the exhaust gas that has flowed into the inner tube 21 serves as the factor of deteriorating the quality of the substrate processing.

In order to address such a problem described above, according to the present embodiments, as shown in FIGS. 5A through 5C, the gas guide R (which collectively refers to a group of gas guide plates including a plurality of fins including a fin 100, a plurality of fins including a fin 200, a plurality of fins including a fin 300, and a fin 400, which are described later) is provided in the exhaust buffer space so as to be capable of controlling the flow of the exhaust gas (that is, the flow path of the exhaust gas) in the exhaust buffer space. In the present specification, the plurality of fins including the fin 100 may also be referred to as “fins 100”, the plurality of fins including the fin 200 may also be referred to as “fins 200”, and the plurality of fins including the fin 300 may also be referred to as “fins 300”.

As shown in FIG. 5A, the gas guide R is provided with the fins 100 and the fins 200. For example, two fins 100 and two fins 200 are provided in the vicinity of each of the gas supply ports 31. Specifically, the gas guide R includes the fins 100 provided such that the gas supply port 31 is interposed therebetween in the vertical direction, that is, directly above and below the gas supply port 31. Further, the gas guide R includes the fins 200 provided such that the gas supply port 31 is interposed therebetween in the horizontal direction, that is, on a left side and a right side of the gas supply port 31. Further, the gas guide R includes the fins 300 at end portions of the fins 200 provided such that the gas supply port 31c is interposed therebetween in the horizontal direction, specifically, at lower end portions of the fins 200. For example, two fins 300 are provided. Further, the gas guide R includes the fin 400 in the vicinity of the first exhaust port 41a, specifically, directly above the first exhaust port 41a. In the present specification, each of the fins 100 provided such that the gas supply port 31a is interposed therebetween in the vertical direction may also be referred to as a “first fin”, and each of the fins 200 provided such that the gas supply port 31a is interposed therebetween in the horizontal direction may also be referred to as a “second fin”. Further, each of the fins 100 provided such that each of the gas supply ports 31b is interposed therebetween in the vertical direction may also be referred to as a “third fin”, and each of the fins 200 provided such that each of the gas supply ports 31b is interposed therebetween in the horizontal direction may also be referred to as a “fourth fin”. Further, each of the fins 300 may also be referred to as a “fifth fin”, and the fin 400 may also be referred to as a “sixth fin”.

Hereinafter, configurations of the first through sixth fins (that is, the fins 100, the fins 200, the fins 300 and the fin 400) included in the gas guide R will be described in detail.

<First Fin and Third Fin>

As shown in FIGS. 4 and 5A, each of the fins 100 serving as the first fin or the third fin is provided on the outer wall of the inner tube 21 in the vicinity of an upper portion or a lower portion of each of the gas supply ports 31 so as to extend in the horizontal direction along an outer periphery of the inner tube 21.

Each of the fins 100 is configured as a gas guide plate protruding from the outer wall of the inner tube 21 toward an inner wall of the outer tube 22, that is, protruding radially outward from the inner tube 21. Each of the fins 100 is configured such that a gap is provided by maintaining a predetermined distance (for example, a distance greater than 2 mm and less than 7 mm) between an end portion of the each of the fins 100 protruding radially outward from the inner tube 21 and the inner wall of the outer tube 22. Each of the fins 100 (including the fin 100 directly above the gas supply port 31a) is oriented parallel to the surfaces (main surfaces) of the wafers W accommodated in a horizontal orientation.

As shown in FIG. 5A, each of the fins 100 is of a horizontal linear shape (that is, of a flat plate shape) when viewed from a side thereof, and a length of each of the fins 100 is set to be a predetermined length (that is, an extension length) greater than an inner diameter of the gas supply port 31 along the horizontal direction. Each of the fins 100 is provided with the same extension length. The fins 100 are provided such that the gas supply port 31 is interposed therebetween in the vertical direction (arrangement direction). The fin 100 directly above the gas supply port 31a is provided below an upper end portion (top plate) of the inner tube 21 by a predetermined distance.

<Second Fin and Fourth Fin>

Further, as shown in FIG. 5A, each of the fins 200 serving as the second fin or the fourth fin is provided on the outer wall of the inner tube 21 in the vicinity of a left portion or a right portion of each of the gas supply ports 31 so as to extend in the vertical direction (arrangement direction).

As shown in FIG. 4, similar to each of the fins 100, each of the fins 200 is configured as a gas guide plate protruding from the outer wall of the inner tube 21 toward the inner wall of the outer tube 22, that is, protruding radially outward from the inner tube 21. Similar to each of the fins 100, each of the fins 200 is configured such that a gap is provided by maintaining a predetermined distance (for example, a distance greater than 2 mm and less than 7 mm) between the end portion of the each of the fins 200 protruding radially outward from the inner tube 21 and the inner wall of the outer tube 22.

As shown in FIGS. 5A and 5B, each of the fins 200 is of a vertical linear shape (that is, of a flat plate shape) when viewed from a side thereof, and a length of each of the fins 200 is set to be a predetermined length (that is, an extension length) greater than an inner diameter of the gas supply port 31 along the vertical direction. The fins 200 are provided such that the gas supply ports 31 are interposed therebetween in the horizontal direction. A first integrated flat plate is constituted by the fins 200 provided on the left sides of the gas supply ports 31. Similarly, a second integrated flat plate is constituted by the fins 200 provided on the right sides of the gas supply ports 31. As shown in FIG. 5B, side surfaces (for example, outer side surfaces in the horizontal direction) of the integrated flat plates are configured as continuous smooth surfaces without steps or gaps.

As shown in FIG. 5A, horizontal end portions of the fins 100 are joined to the fins 200 provided on both sides in the horizontal direction. As a result, an outer periphery of each of the gas supply ports 31 is surrounded (continuously) by the fins 100 and the fins 200 without any gaps.

<Fifth Fin>

As shown in FIG. 5A, each of the two fins 300, which serves as the fifth fin, is provided on the outer wall of the inner tube 21 below the gas supply port 31c (and the gas supply ports 31) so as to extend in the vertical direction (arrangement direction), that is, so as to extend toward the second exhaust port 91 with a predetermined length (that is, an extension length). The two fins 300 extends downward from the lower end portions of the two fins 200 (which are provided such that the gas supply port 31c is interposed therebetween in the horizontal direction). For example, a lower end portion of each of the two fins 300 is located in the vicinity of a lower end portion of the heater 10 and above the lower end portion of the heater 10 (see FIG. 1).

Similar to the fins 100 and the fins 200, each of the two fins 300 is configured as a gas guide plate protruding from the outer wall of the inner tube 21 toward the inner wall of the outer tube 22, that is, protruding radially outward from the inner tube 21. Similar to the fins 100 and the fins 200, each of the two fins 300 is configured such that a gap is provided by maintaining a predetermined distance (for example, a distance greater than 2 mm and less than 7 mm) between an end portion of the each of the two fins 300 protruding radially outward from the inner tube 21 and the inner wall of the outer tube 22.

As shown in FIGS. 5A and 5B, each of the two fins 300 is of a vertical linear shape (that is, of a flat plate shape) when viewed from a side thereof. The first integrated flat plate is constituted by the fin 300 and the fins 200 provided on the left sides of the gas supply ports 31. Similarly, the second integrated flat plate is constituted by the fin 300 and the fins 200 provided on the right sides of the gas supply ports 31. As shown in FIG. 5B, the side surfaces (for example, the outer side surfaces in the horizontal direction) of the integrated flat plates are configured as continuous smooth surfaces without steps or gaps.

<Sixth Fin>

As shown in FIGS. 5B and 5C, the fin 400 serving as the sixth fin is provided on the outer wall of the inner tube 21 above upper ends of the first exhaust ports 41 (that is, provided in the vicinity of and above an upper end of the first exhaust port 41a) so as to extend in the horizontal direction along the outer periphery of the inner tube 21. The fin 400 is of a horizontal linear shape (that is, of a flat plate shape) when viewed from a side thereof, and a length of the fin 400 is set to be a predetermined length (that is, an extension length) greater than an inner diameter of the first exhaust port 41a along the horizontal direction. The fin 400 is provided below the upper end portion (top plate) of the inner tube 21 by a predetermined distance.

Similar to the fins 100, the fins 200 and the fins 300, the fin 400 is configured as a gas guide plate protruding from the outer wall of the inner tube 21 toward the inner wall of the outer tube 22, that is, protruding radially outward from the inner tube 21. The fin 400 is configured such that a gap is provided by maintaining a predetermined distance (for example, a distance greater than 2 mm and less than 7 mm) between an end portion of the fin 400 protruding radially outward from the inner tube 21 and the inner wall of the outer tube 22.

### (4) Effects According to Present Embodiments

According to the present embodiments described above, it is possible to obtain at least one among the following effects.

(a) The gas guide R according to the present embodiments includes the fins configured to surround at least a part of the outer periphery of the gas supply port 31a in the vicinity of the gas supply port 31a. Thereby, it is possible to prevent (or suppress) the exhaust gas flowing in the exhaust buffer space from flowing into the inner tube 21 through the gas supply port 31a. As a result, it is possible to improve the quality of the substrate processing, in particular, the quality of the substrate processing with respect to the wafer W arranged on an upper portion of the substrate accommodating region 65.

(b) The gas guide R according to the present embodiments includes the fins 100 (first fin) in the vicinity of the gas supply port 31a so as to extend in the horizontal direction. The length of each of the fins 100 is set to be the predetermined length greater than an inner diameter of the gas supply port 31a along the horizontal direction. The fins 100 are provided such that the gas supply port 31a is interposed therebetween in the arrangement direction (vertical direction). Thereby, it is possible to prevent (or suppress) the exhaust gas flowing in the exhaust buffer space from flowing into the gas supply port 31a. As a result, it is possible to improve the quality of the substrate processing, in particular, the quality of the substrate processing with respect to the wafer W arranged on the upper portion of the substrate accommodating region 65.

(c) The gas guide R according to the present embodiments includes the fins 200 (second fin) in the vicinity of the gas supply port 31a so as to extend in the arrangement direction (vertical direction). The length of each of the fins 200 is set to be the predetermined length greater than the inner diameter of the gas supply port 31a in the arrangement direction (vertical direction). The fins 200 are provided such that the gas supply port 31a is interposed therebetween in the horizontal direction. Thereby, it is possible to prevent (or suppress) the exhaust gas flowing in the exhaust buffer space from flowing into the gas supply port 31a. As a result, it is possible to improve the quality of the substrate processing, in particular, the quality of the substrate processing with respect to the wafer W arranged on the upper portion of the substrate accommodating region 65.

(d) The gas guide R according to the present embodiments includes the fins 100 (third fin) in the vicinity of the gas supply ports 31b so as to extend in the horizontal direction. The length of each of the fins 100 is set to be the predetermined length greater than the inner diameter of each of the gas supply ports 31b in the horizontal direction. The fins 100 are provided such that each of the gas supply ports 31b is interposed therebetween in the arrangement direction (vertical direction). Thereby, it is possible to prevent (or suppress) the exhaust gas flowing in the exhaust buffer space from flowing into the gas supply ports 31b. As a result, it is possible to improve the quality of the substrate processing, in particular, the quality of the substrate processing even with respect to such wafers W arranged on a portion other than the upper portion of the substrate accommodating region 65.

(e) The gas guide R according to the present embodiments includes the fins 200 (fourth fin) in the vicinity of the gas supply ports 31b so as to extend in the arrangement direction (vertical direction). The length of each of the fins 200 is set to be the predetermined length greater than the inner diameter of each of the gas supply ports 31b in the arrangement direction (vertical direction). The fins 200 are provided such that each of the gas supply ports 31b is interposed therebetween in the horizontal direction. Thereby, it is possible to prevent (or suppress) the exhaust gas flowing in the exhaust buffer space from flowing into the gas supply ports 31b. As a result, it is possible to improve the quality of the substrate processing, in particular, the quality of the substrate processing even with respect to such wafers W arranged on the portion other than the upper portion of the substrate accommodating region 65.

(f) The gas guide R according to the present embodiments includes the fins 300 (fifth fin) so as to extend from the end portions of the fins 200 provided in the vicinity of the gas supply port 31c in the arrangement direction (vertical direction) with the predetermined length. As a result, it is possible to improve the quality of the substrate processing, in particular, the quality of the substrate processing with respect to the wafer W arranged on a lower portion of the substrate accommodating region 65.

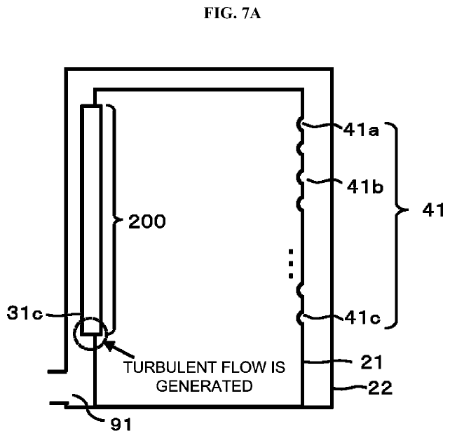

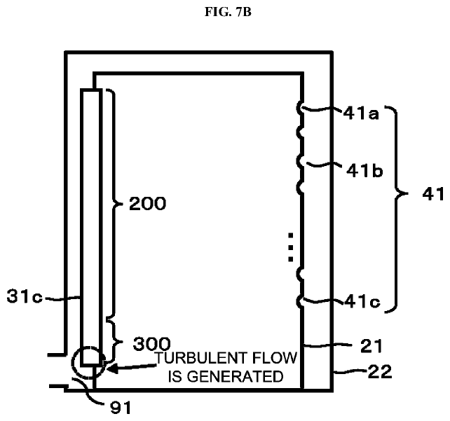

On the other hand, when the fins 300 are not provided, a turbulent flow of the exhaust gas may be generated at a location shown by a broken line in FIG. 7A, that is, around the gas supply port 31c, and a small amount of the exhaust gas may flow into the gas supply port 31c under an influence of the turbulent flow. In such a case, although the effects described above can be sufficiently obtained, the quality of the substrate processing (in particular, the quality of the substrate processing with respect to the wafer W arranged on the lower portion of the substrate accommodating region 65) may be affected within a range in which the effects can be obtained.

In order to address such a problem described above, by providing the fins 300, as shown by a broken line in FIG. 7B, the location at which the turbulent flow of the exhaust gas is generated can be kept away from the gas supply port 31c. Thereby, it is possible to prevent (or suppress) the exhaust gas from flowing into the gas supply port 31c. As a result, it is possible to improve the quality of the substrate processing, in particular, the quality of the substrate processing with respect to the wafer W arranged on the lower portion of the substrate accommodating region 65.

(g) In the gas guide R according to the present embodiments, the first integrated flat plate is constituted by the fin 300 and the fins 200 provided on the left sides of the gas supply ports 31. Further, the second integrated flat plate is constituted by the fin 300 and the fins 200 provided on the right sides of the gas supply ports 31. In addition, the side surfaces (for example, the outer side surfaces in the horizontal direction) of the integrated flat plates are configured as continuous smooth surfaces without steps or gaps. Thereby, it is possible to prevent (or suppress) the turbulent flow from being generated in the exhaust buffer space, and as a result, it is possible to improve the quality of the substrate processing.

(h) The gas guide R according to the present embodiments includes the fin 400 (sixth fin) in the vicinity of the first exhaust port 41a so as to extend in the horizontal direction. The length of the fin 400 is set to be the predetermined length greater than the inner diameter of the first exhaust port 41a in the horizontal direction. Thereby, it is possible to prevent (or suppress) the exhaust gas discharged through the first exhaust ports 41 (in particular, the first exhaust port 41a) from flowing in the upper buffer space. Further, it is possible to prevent (or suppress) the exhaust gas from flowing into the gas supply port 31a via the upper buffer space. As a result, it is possible to improve the quality of the substrate processing with respect to the wafer W, in particular, the quality of the substrate processing with respect to the wafer W arranged on the upper portion of the substrate accommodating region 65.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the embodiments described above are described by way of an example in which the fins 100 serving as the first fin or the third fin are provided on both sides (that is, above and below) of the gas supply ports 31, and the fins 200 serving as the second fin or the fourth fin are provided on both sides (that is, the left sides and the right sides) of the gas supply ports 31. However, the technique of the present disclosure is not limited thereto. For example, the fins 100 may be provided on one of above and below the gas supply ports 31, and the fins 200 may be provided on one of the left sides and the right sides of the gas supply ports 31. Even in such cases, it is possible to obtain at least a part of the effects of the embodiments described above.

For example, the embodiments described above are described by way of an example in which each of the fins 300 serving as the fifth fin is provided so as to extend from the lower end portions of the two fins 200 (which are provided such that the gas supply port 31c is interposed therebetween in the horizontal direction), that is, the two fins 300 are provided. However, the technique of the present disclosure is not limited thereto. For example, the fin 300 may be provided so as to extend from the lower end portion of one of the two fins 200 (which are provided such that the gas supply port 31c is interposed therebetween in the horizontal direction), that is, a single fin serving as the fin 300 may be provided. Even in such a case, it is possible to obtain at least a part of the effects of the embodiments described above.

For example, the embodiments described above are described by way of an example in which the fins 100, the fins 200, the fins 300 and the fin 400 are provided. However, the technique of the present disclosure is not limited thereto. For example, the fin 100 may be provided directly above the gas supply port 31a and the other fins may be omitted. Even in such a case, it is possible to obtain at least a part of the effects of the embodiments described above.

For example, the embodiments described above are described by way of an example in which each of the gas supply ports 31 is individually surrounded by the fins 100 and the fins 200. However, the technique of the present disclosure is not limited thereto. For example, several gas supply ports 31 (for example, two gas supply ports 31 to five gas supply ports 31) may be defined as one unit, and each unit (several gas supply ports 31) may be collectively surrounded by the fins 100 and the fins 200. Even in such a case, it is possible to obtain substantially the same effects as the embodiments described above.

For example, the embodiments described above are described by way of an example in which the fins 100 are provided with the same extension length. However, the technique of the present disclosure is not limited thereto. For example, the extension length of the fin 100 directly above the gas supply port 31a may be set to be the longest, and the extension length of each of the fins 100 other than the fin 100 directly above the gas supply port 31a may be gradually shortened as a position of each of the fin 100 is lowered. Even in such a case, it is possible to obtain substantially the same effects as the embodiments described above. However, when the fins 100 are provided with the same extension length as in the embodiments described above, it is more preferable in that it is possible to prevent (or suppress) the gas discharged through the first exhaust ports 41 into the exhaust buffer space from flowing into the gas supply ports 31.

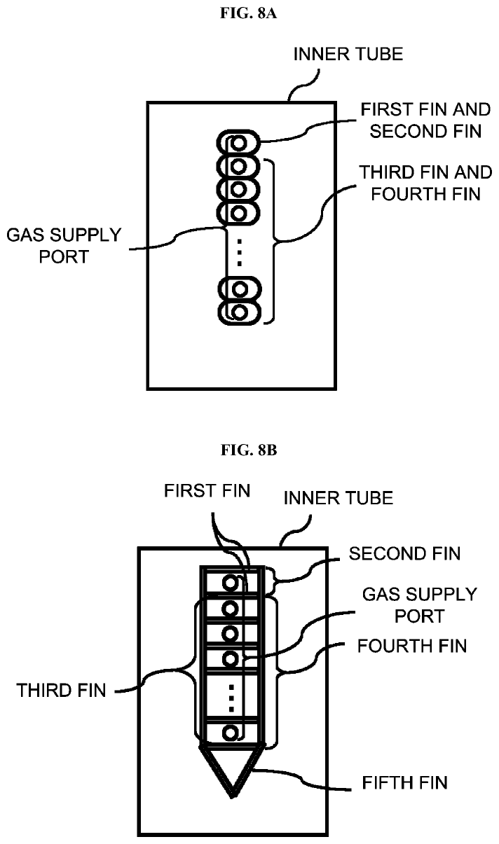

For example, the embodiments described above are described by way of an example in which each of the first fin and the second fin (that is, the fins 100 and the fins 200) is configured in a flat plate shape, the first integrated flat plate is constituted by the fins 200 provided on the left sides of the gas supply ports 31 and the second integrated flat plate is constituted by the fins 200 provided on the right sides of the gas supply ports 31. However, the technique of the present disclosure is not limited thereto. For example, the fins 100 and the fins 200 may be curved and integrated so as to form a continuous curved surface, the outer periphery of each of the gas supply ports may be surrounded by the curved fins in a circular or elliptical shape when the inner tube is viewed from a direction of the gas supply ports as shown in FIG. 8A. Even in such a case, it is possible to obtain substantially the same effects as the embodiments described above. However, when the gas supply ports 31 are surrounded by the fins 100 and the fins 200 (which are of linear shapes) without any gaps as in the embodiments described above, it is more preferable in that it is possible to prevent (or suppress) the turbulent flow from being generated in the exhaust buffer space.

For example, the embodiments described above are described by way of an example in which the fins 100 and the fins 200 are configured such that the gap of the same distance is maintained between the end portion of each of the fins 100 (or the end portion of each of the fins 200) protruding radially outward from the inner tube 21 and the inner wall of the outer tube 22. However, the technique of the present disclosure is not limited thereto. For example, a size of each of the fins 100 (a protrusion amount of each of the fins 100 protruding from the outer wall of the inner tube 21) may be set such that the gap at the fin 100 directly above the gas supply port 31a is the shortest. Further, for example a size of each of the fins 200 (a protrusion amount of each of the fins 200 protruding from the outer wall of the inner tube 21) may be set such that the gap at the fins 200 provided on both sides (that is, the left side and the right side) of the gas supply port 31a is the shortest. Thereby, it is possible to more reliably prevent (or suppress) the exhaust gas flowing in the exhaust buffer space from flowing into the gas supply port 31a.

For example, the embodiments described above are described by way of an example in which each of the fins 100 (including the fin 100 directly above the gas supply port 31a) is oriented parallel to the surfaces (main surfaces) of the wafers W accommodated in the horizontal orientation. However, the technique of the present disclosure is not limited thereto. For example, the fin 100 directly above the gas supply port 31a may be oriented in which the end portion of the fin 100 is elevated or lowered as the fin 100 protrudes radially further outward from the inner tube 21, that is, in an inclined orientation. The other fins 100 may be oriented in the same manner. Even in such a case, it is possible to obtain at least a part of the effects of the embodiments described above.

For example, the embodiments described above are described by way of an example in which the upper end of the inner tube 21 is closed. However, the technique of the present disclosure is not limited thereto. For example, an inner tube 21 with an open upper end, that is, the inner tube 21 without the top plate at the upper end thereof may be used. Even in such a case, by providing the various fins described above, it is possible to obtain at least a part of the effects of the embodiments described above. Further, when the upper end of the inner tube 21 is open, the exhaust gas discharged through at least one of the first exhaust ports 41 and flowing into the upper buffer space may be easily flow into the inner tube 21 through an opening at the upper end of the inner tube 21. With respect to such a problem, when the fin 400 serving as the sixth fin is provided, it is particularly significant in that it is possible to prevent (or suppress) the exhaust gas discharged through at least one of the first exhaust ports 41 from flowing into the upper buffer space.

For example, the embodiments described above are described by way of an example in which the fin 100 directly above the gas supply port 31a is provided below the upper end portion of the inner tube 21. However, the technique of the present disclosure is not limited thereto. For example, the fin 100 directly above the gas supply port 31a may be provided at the same height as the upper end portion of the inner tube 21. Even in such a case, it is possible to obtain at least a part of the effects of the embodiments described above. Further, when the fin 100 directly above the gas supply port 31a is provided at the same height as the upper end portion of the inner tube 21, it is possible to provide a flat surface without a step between the upper end portion of the inner tube 21 and the fin 100 directly above the gas supply port 31a. Thereby, it is possible to prevent (or suppress) the turbulent flow from being generated in the vicinity of the upper end portion of the inner tube 21. As a result, it is possible to prevent (or suppress) the exhaust gas from flowing into the inner tube 21 through the gas supply port 31a. Further, it is also possible to prevent (or suppress) the exhaust gas from flowing into the inner tube 21 when the upper end of the inner tube 21 is open.

For example, the embodiments described above are described by way of an example in which the fin 400 serving as the sixth fin directly above the first exhaust port 41a is provided below the upper end portion of the inner tube 21. However, the technique of the present disclosure is not limited thereto. For example, the fin 400 may be provided at the same height as the upper end portion of the inner tube 21. Even in such a case, it is possible to obtain at least a part of the effects of the embodiments described above. Further, when the fin 400 directly above the first exhaust port 41a is provided at the same height as the upper end portion of the inner tube 21, it is possible to provide a flat surface without a step between the upper end portion of the inner tube 21 and the fin 400. Thereby, it is possible to prevent (or suppress) the turbulent flow from being generated in the vicinity of the upper end portion of the inner tube 21. As a result, it is possible to stably exhaust the gas through the first exhaust port 41a. Further, it is also possible to prevent (or suppress) the exhaust gas from flowing into the inner tube 21 due to the turbulent flow when the upper end of the inner tube 21 is open.

For example, the embodiments described above are described by way of an example in which the front end (tip) of the nozzle 30 is provided outside the inner tube 21 as shown in FIG. 1 and the gas is supplied into the inner tube 21 through an outside of the inner tube 21. However, the technique of the present disclosure is not limited thereto. For example, the front end (tip) of the nozzle 30 may be provided inside the inner tube 21 and the gas may be supplied into the inner tube 21 through an inside of the inner tube 21. Even in such a case, it is possible to obtain substantially the same effects as the embodiments described above. Further, by providing the front end (tip) of the nozzle 30 inside the inner tube 21, it is also possible to prevent (or suppress) the exhaust gas from flowing into the inner tube 21 when the gas is supplied into the inner tube 21 through the nozzle 30.

For example, the embodiments described above are described by way of an example in which each of the fins 300 serving as the fifth fin is provided so as to extend downward in the vertical direction from the lower end portion of each of the fins 200 provided on the lowermost locations, which serves as the second fin. However, the technique of the present disclosure is not limited thereto. For example, one or both of the two fins 300 serving as the fifth fin may be inclined at a predetermined angle with respect to the vertical direction from the lower end portion of one or both of the two fins 200 provided on the lowermost locations, which serves (or serve) as the second fin. That is, not only a vertical component but also a horizontal component may be included in an extending direction of one or both of the two fins 300 serving as the fifth fin. Even in such a case, it is possible to obtain substantially the same effects as the embodiments described above.

For example, as shown in FIG. 8B, when each of the two fins 300 serving as the fifth fin are provided so as to extend downward in the vertical direction from the lower end portion of each of the fins 200 provided on the lowermost locations, which serves as the second fin, one or both of the two fins 300 may be inclined at a predetermined angle with respect to the vertical direction such that the two fins 300 join at downstream ends (lower ends) thereof. Even in such a case, it is possible to obtain substantially the same effects as the embodiments described above. Further, by joining the two fins 300 at the downstream ends thereof, it is possible to reduce the number of the locations at which the turbulent flow of the exhaust gas is generated from two to one, and it is also possible to further reduce a possibility of the exhaust gas flowing into the gas supply port. As a result, it is possible to improve the quality of the substrate processing, in particular, the quality of the substrate processing with respect to the wafer W arranged on the lower portion of the substrate accommodating region 65.

For example, the embodiments described above are described by way of an example in which the first exhaust ports 41 are provided on the side wall of the inner tube 21 at the positions facing the gas supply ports 31, respectively, via the substrate accommodating region 65. However, the technique of the present disclosure is not limited thereto. For example, the first exhaust ports 41 may be provided on the side wall of the inner tube 21 at positions shifted by a predetermined distance along a circumferential direction of the side wall of the inner tube 21 from the positions facing the gas supply ports 31, respectively, via the substrate accommodating region 65. Even in such a case, it is possible to obtain substantially the same effects as the embodiments described above.

For example, the embodiments described above are described by way of an example in which the gas supply ports 31 and the first exhaust ports 41 are provided corresponding to the wafers W accommodated in the substrate accommodating region 65, respectively. However, the technique of the present disclosure is not limited thereto. For example, at least one among the gas supply ports 31 or the first exhaust ports 41, or both of the gas supply ports 31 and the first exhaust ports 41 may be provided corresponding to some of the wafers W (for example, at intervals of 2 wafers to 5 wafers) accommodated in the substrate accommodating region 65. Even in such a case, it is possible to obtain substantially the same effects as the embodiments described above.

For example, the embodiments described above are described by way of an example in which the SiN film is formed on the wafer W. However, the technique of the present disclosure is not limited thereto. For example, the technique of the present disclosure may be preferably applied to form a film such as a silicon film (Si film), a silicon oxide film (SiO film) and a silicon oxynitride film (SiON film) on the wafer W. Further, the technique of the present disclosure may be preferably applied to form a metal-based film such as a titanium film (Ti film), a titanium oxide film (TiO film), a titanium nitride film (TiN film), an aluminum film (Al film), an aluminum oxide film (AlO film) and a hafnium oxide film (HfO) on the wafer W. Even in such a case, it is possible to obtain substantially the same effects as the embodiments described above.

The technique of the present disclosure is not limited to a process of forming the film on each of the wafers W. For example, the technique of the present disclosure may be preferably applied when a process such as an etching process, an annealing process and a plasma modification process is performed on each of the wafers W. Even in such a case, it is possible to obtain substantially the same effects as the embodiments described above.

According to some embodiments of the present disclosure, it is possible to improve the quality of the processing on the substrate when the substrate is processed.

What is claimed is:

1. A substrate processing apparatus comprising:
an inner tube provided with a substrate accommodating region therein in which a plurality of substrates are accommodated in a multistage manner along a predetermined arrangement direction while the plurality of substrates are horizontally oriented;
an outer tube provided outside the inner tube;
a plurality of gas supply ports provided on a side wall of the inner tube along the arrangement direction;
a plurality of first exhaust ports provided on the side wall of the inner tube along the arrangement direction;
a second exhaust port provided at an end portion of the outer tube along the arrangement direction; and
a gas guide configured to be capable of controlling a flow of a gas in an annular space between the inner tube and the outer tube,
wherein a first exhaust port A among the plurality of first exhaust ports is located farthest from the second exhaust port, and a gas supply port A among the plurality of gas supply ports faces the first exhaust port A, and
wherein the gas guide comprises a fin provided in a vicinity of the gas supply port A and configured to surround at least a part of an outer periphery of the gas supply port A.

2. The substrate processing apparatus of claim 1, wherein the second exhaust port is provided at a position opposite to the plurality of first exhaust ports with the substrate accommodating region interposed therebetween.

3. The substrate processing apparatus of claim 1, wherein the gas guide comprises a first fin or two first fins provided in a vicinity of the gas supply port A so as to extend in a horizontal direction, and
wherein a length of the first fin or each of the two first fins is set to be a predetermined length greater than an inner diameter of the gas supply port A along the horizontal direction.

4. The substrate processing apparatus of claim 3, wherein the two first fins are provided in the vicinity of the gas supply port A such that the gas supply port A is interposed therebetween in the arrangement direction.

5. The substrate processing apparatus of claim 1, wherein the gas guide comprises a second fin or two second fins provided in a vicinity of the gas supply port A so as to extend in the arrangement direction, and
wherein a length of the second fin or each of the two second fins is set to be a predetermined length greater than an inner diameter of the gas supply port A along the arrangement direction.

6. The substrate processing apparatus of claim 5, wherein the two second fins are provided in the vicinity of the gas supply port A such that the gas supply port A is interposed therebetween in a horizontal direction.

7. The substrate processing apparatus of claim 1, wherein first exhaust ports B among the plurality of first exhaust ports other than the first exhaust port A are configured to face gas supply ports B among the plurality of gas supply ports other than the gas supply port B, respectively, and
wherein the gas guide comprises a third fin or two third fins provided in a vicinity of each of the gas supply ports B so as to extend in a horizontal direction, and
wherein a length of the third fin or each of the two third fins is set to be a predetermined length greater than an inner diameter of each of the gas supply ports B along the horizontal direction.

8. The substrate processing apparatus of claim 7, wherein the two third fins are provided in the vicinity of each of the gas supply ports B such that each of the gas supply ports B is interposed therebetween in the arrangement direction.

9. The substrate processing apparatus of claim 1, wherein first exhaust ports B among the plurality of first exhaust ports other than the first exhaust port A are configured to face gas supply ports B among the plurality of gas supply ports other than the gas supply port A, respectively, and
wherein the gas guide comprises a fourth fin or two fourth fins provided in a vicinity of each of the gas supply ports B so as to extend in the arrangement direction, and
wherein a length of the fourth fin or each of the two fourth fins is set to be a predetermined length greater than an inner diameter of each of the gas supply ports B along the arrangement direction.

10. The substrate processing apparatus of claim 9, wherein the two fourth fins are provided in the vicinity of each of the other gas supply ports B such that each of the gas supply ports B is interposed therebetween in a horizontal direction.

11. The substrate processing apparatus of claim 9, wherein a first exhaust port C among the plurality of first exhaust ports is provided closest to the second exhaust port and a gas supply port C among the plurality of gas supply ports faces the first exhaust port C, and
wherein the gas guide comprises a fifth fin or two fifth fins extending with a predetermined length from one or two end portions of the fourth fin or the two fourth fins provided in the vicinity of the gas supply port C in the arrangement direction or in a direction toward the second exhaust port.

12. The substrate processing apparatus of claim 11, wherein a gap is provided between an end portion of the fifth fin or each of the two fifth fins and an end portion of the side wall of the inner tube.

13. The substrate processing apparatus of claim 11, wherein the two fifth fins extend from the two end portions of the two fourth fins provided in the vicinity of the gas supply port B, and
wherein end portions of the two fifth fins facing the second exhaust port are in contact with each other.

14. The substrate processing apparatus of claim 1, wherein the gas guide comprises a sixth fin provided in a vicinity of the first exhaust port A between the first exhaust port A and the gas supply port A so as to extend in a horizontal direction, and
wherein a length of the sixth fin is set to be a predetermined length greater than an inner diameter of the first exhaust port A along the horizontal direction.

15. The substrate processing apparatus of claim 1, wherein the plurality of first exhaust ports are provided at positions opposite to the plurality of gas supply ports with the substrate accommodating region interposed therebetween, respectively.

16. A substrate processing method comprising:
(a) accommodating a plurality of substrates in a substrate accommodating region of an inner tube in a multistage manner along a predetermined arrangement direction while the plurality of substrates are horizontally oriented;
(b) supplying a gas into the inner tube through a plurality of gas supply ports provided on a side wall of the inner tube along the arrangement direction;
(c) discharging the gas supplied into the inner tube to an outer tube provided outside the inner tube through a plurality of first exhaust ports provided on the side wall of the inner tube along the arrangement direction;
(d) exhausting an annular space between the inner tube and the outer tube through a second exhaust port provided at an end portion of the outer tube along the arrangement direction, wherein a first exhaust port A among the plurality of first exhaust ports is provided farthest from the second exhaust port and a gas supply port A among the plurality of gas supply ports faces the first exhaust port A; and
(e) controlling a flow of the gas in the annular space by using a gas guide comprising a fin provided in a vicinity of the gas supply port A and configured to surround at least a part of an outer periphery of the gas supply port A.

17. A method of manufacturing a semiconductor device, comprising the substrate processing method of claim 16.

18. A non-transitory computer-readable recording medium storing a program that causes, by a computer, a substrate processing apparatus to perform the substrate processing method of claim 16.

19. An inner tube comprising
a substrate accommodating region in which a plurality of substrates are accommodated in a multistage manner along a predetermined arrangement direction while the plurality of substrates are horizontally oriented,
wherein the inner tube is provided inside an outer tube at which a second exhaust port is provided at an end portion of the outer tube along the arrangement direction, and
wherein a plurality of gas supply ports are provided on a side wall of the inner tube along the arrangement direction, and
wherein a plurality of first exhaust ports is provided on the side wall of the inner tube along the arrangement direction, and
wherein a first exhaust port A among the plurality of first exhaust ports is provided farthest from the second exhaust port and a gas supply port A among the plurality of gas supply ports faces the first exhaust port A, and
wherein a fin constituting at least a part of a gas guide configured to be capable of controlling a flow of a gas in an annular space between the inner tube and the outer tube is provided on the side wall of the inner tube in a vicinity of the gas supply port A and configured to surround at least a part of an outer periphery of the gas supply port A.
